(19) United States
(12) Patent Application Publication
(10) Pub. No.: US 2015/0115361 A1
(43) Pub. Date: Apr. 30, 2015

(54) Lateral Diffused Metal Oxide Semiconductor

(71) Applicants: Himax Technologies Limited, Tainan City (TW); National Chiao Tung University, Hsinchu City (TW); Himax Analogic, Inc., Tainan City (TW)

(72) Inventors: Chao-Yuan Su, Tainan City (TW); Ching-Yi Wu, Tainan City (TW); Hung-Bin Chen, Hsinchu City (TW); Chun-Yen Chang, Hsinchu City (TW)

(73) Assignees: Himax Technologies Limited, Tainan City (TW); National Chiao Tung University, Hsinchu City (TW); Himax Analogic, Inc., Tainan City (TW)

(21) Appl. No.: 14/066,891

(22) Filed: Oct. 30, 2013

(51) Int. Cl. H01L 29/78; H01L 29/10

(52) U.S. Cl. CPC H01L 29/7816; H01L 29/1095
USPC 257/336

(57) ABSTRACT

A lateral diffused N-type metal oxide semiconductor device includes a semiconductor substrate, an epi-layer on the semiconductor substrate, a patterned isolation layer on the epi-layer, a N-type double diffused drain (NDDD) region in a first active region of the patterned isolation layer, a N+ heavily doped drain region disposed in the NDDD region, a P-body diffused region disposed in a second active region of the patterned isolation layer, a neighboring pair of a N+ heavily doped source region and a P+ heavily doped source region disposed in the P-body diffused region, a first gate structure disposed above a channel region of the patterned isolation layer and a second gate structure disposed above the second active region. The second gate structure and the first gate structure are spaced at a predetermined distance.

### BACKGROUND

1. Field of Invention

The present disclosure relates to a metal oxide semiconductor device. More particularly, the present disclosure relates to a lateral diffused N-type or P-type metal oxide semiconductor device.

2. Description of Related Art

Single-chip systems have been developed, which include controllers, memory devices, low-voltage (LV) circuits and high-voltage (HV) power devices. For example, double-diffused metal oxide semiconductor (DMOS) transistors, which are frequently used as conventional power devices operated with low on-resistance and high voltage.

When a transistor is designed, high breakdown voltage (BV) and low on-resistance (Rₒₙ) are two main concerns. However, by using very-large-scale integration (VLSI) technology, a high-voltage lateral double-diffused metal oxide semiconductor (LDMOS) may have higher on-resistance than a commonly used vertical double-diffused metal oxide semiconductor (VDMOS). How to decrease the on-resistance becomes an important factor for promoting a figure of merit (FOM), ie., a ratio of BV/Rₒₙ.

### SUMMARY

The present disclosure provides a lateral diffused N-type metal oxide semiconductor (LDNMOS) device and a lateral diffused P-type diffused metal oxide semiconductor (LDPMOS) device for decreasing on-resistance of the LDNMOS device and the LDPMOS device.

An aspect of the present disclosure is to provide a LDNMOS device. The device includes a semiconductor substrate, an epi-layer, a patterned isolation layer, a N-type double diffused drain (NDDD) region, a N+ heavily doped drain region, a P-body diffused region, a neighboring pair of a N+ heavily doped source region and a P+ heavily doped source region, a first gate structure and a second gate structure. The epi-layer is on the semiconductor substrate. The patterned isolation layer is disposed on the epi-layer, thereby defining a first active region, a second active region and a channel region, in which the channel region is located between the first active region and the second active region. The NDDD region is disposed in the first active region. The N+ heavily doped drain region is disposed in the NDDD region. The P-body diffused region is disposed in the second active region, in which the NDDD region and the P-body diffused region are spaced at a first predetermined distance to expose the epi-layer. The neighboring pair of the N+ heavily doped source region and the P+ heavily doped source region is disposed in the P-body diffused region. The first gate structure is disposed above the channel region. The second gate structure is disposed above the second active region, in which the second gate structure and the first gate structure are spaced at a second predetermined distance.

In one or more embodiments, the second gate structure has an extending portion extending from an interface toward the first gate structure and disposed on the channel portion, in which the interface is located between the P-body diffused region and the channel region.

In one or more embodiments, a ratio of a length of the extending portion to the first predetermined distance is in a range substantially from 0.13 to 0.52.

In one or more embodiments, a ratio of a length of the extending portion to the first predetermined distance is in a range substantially from 0.35 to 0.52.

In one or more embodiments, the second predetermined distance is in a range substantially from 0.1 μm to 10 μm.

In one or more embodiments, further including a gate dielectric layer disposed between the first gate structure and the channel region.

In one or more embodiments, a thickness of the gate dielectric layer is in a range substantially from 12 nm to 100 nm.

In one or more embodiments, the gate dielectric layer is formed from SiO₂.

In one or more embodiments, the gate dielectric layer is disposed between the second gate structure and the second active region.

In one or more embodiments, a length of the first gate structure is in a range substantially from 1 nm to 1000 nm.

Another aspect of the present disclosure is to provide a LDPMOS device. The device includes a semiconductor substrate, an epi-layer, a patterned isolation layer, a P-type double diffused drain (PDDD) region, a P+ heavily doped drain region, a N-body diffused region, a neighboring pair of a P+ heavily doped source region and a N+ heavily doped source region, a first gate structure and a second gate structure. The epi-layer is on the semiconductor substrate. The patterned isolation layer is disposed on the epi-layer, thereby defining a first active region, a second active region and a channel region, in which the channel region is located between the first active region and the second active region. The PDDD region is disposed in the first active region. The P+ heavily doped drain region is disposed in the PDDD region. The P-body diffused region is disposed in the second active region, in which the NDDD region and the N-body diffused region are spaced at a first predetermined distance to expose the epi-layer. The neighboring pair of the P+ heavily doped source region and the N+ heavily doped source region are disposed in the N-body diffused region. The first gate structure is disposed above the channel region. The second gate structure is disposed above the second active region, in which the second gate structure and the first gate structure are spaced at a second predetermined distance.

In one or more embodiments, the second gate structure has an extending portion extending from an interface toward the first gate structure and disposed on the channel portion, in which the interface is located between the P-body diffused region and the channel region.

In one or more embodiments, a ratio of a length of the extending portion to the first predetermined distance is in a range substantially from 0.13 to 0.52.

In one or more embodiments, a ratio of a length of the extending portion to the first predetermined distance is in a range substantially from 0.35 to 0.52.

In one or more embodiments, the second predetermined distance is in a range substantially from 0.1 μm to 10 μm.

In one or more embodiments, further including a gate dielectric layer disposed between the first gate structure and the channel region.

In one or more embodiments, a thickness of the gate dielectric layer is in a range substantially from 12 nm to 100 nm.

In one or more embodiments, the gate dielectric layer is formed from SiO₂.

In one or more embodiments, the gate dielectric layer is disposed between the second gate structure and the second active region.

In one or more embodiments, a length of the first gate structure is in a range substantially from 1 nm to 1000 nm.

According to the above, compared with the conventional technology, the technical solution of the present disclosure has obvious advantages and beneficial effects. By using the aforementioned technical measures, the present disclosure can make quite a technical progress, and has wide industrial application values. The device of the present disclosure can achieve decreasing the on-resistance by the first gate structure electrically connecting to an input voltage. Further, the FOM of the LDNMOS device and the LDPMOS device can be also promoted.

### BRIEF DESCRIPTION OF THE DRAWINGS

FIG. 1 is a schematic diagram showing a LDNMOS device in accordance with an embodiment of the present disclosure; and

FIG. 2 is a schematic diagram showing a LDPMOS device in accordance with another embodiment of the present disclosure.

### DETAILED DESCRIPTION

The spirit of the present disclosure is described as figures and detailed description in considerable detail. It will be apparent to those skilled in the art that, after understanding the preferred embodiments of the present disclosure, various modifications and variations can be made to the features disclosed in the present disclosure without departing from the scope or spirit of the disclosure.

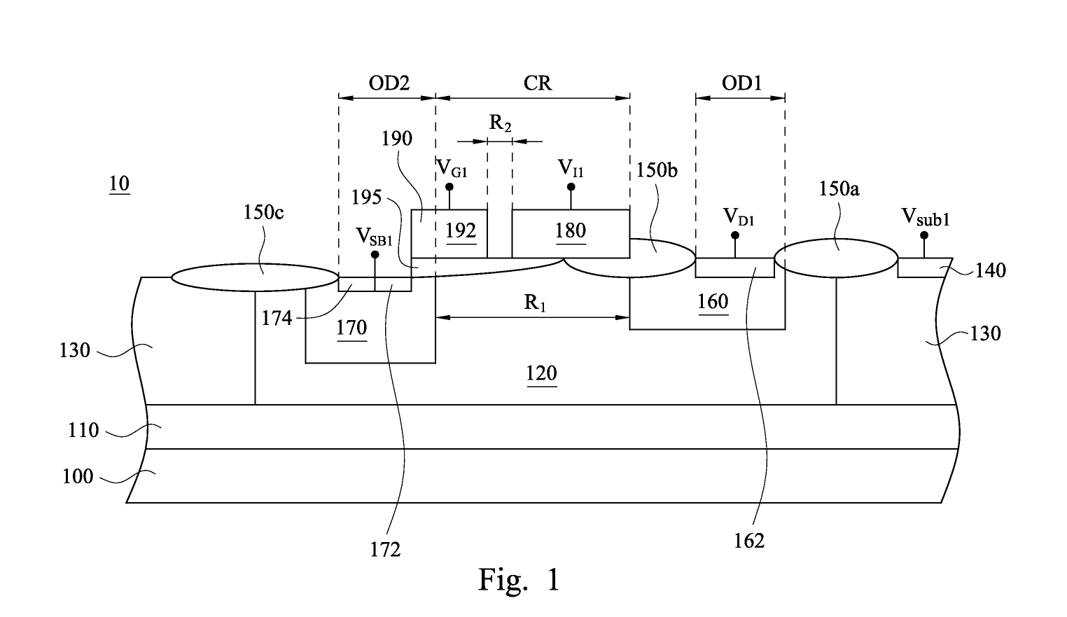

Referring to FIG. 1, FIG. 1 is a schematic diagram showing a LDNMOS device in accordance with an embodiment of the present disclosure. In FIG. 1, a LDNMOS device 10 includes a semiconductor substrate 100 such as a P-type silicon substrate with an epitaxial layer (epi-layer) 110 thereon. The epi-layer 110 includes a high voltage N-well (HVNW) region 120 enclosed by a high voltage P-well (HVPW) region 130. The surface of the high voltage P-well (HVPW) region 130 includes a P+ heavily diffused region 140, in which a substrate voltage V_{sub1} is applied to the P+ heavily diffused region 140.

Patterned isolations 150a, 150b and 150c are disposed on the epi-layer 110, thereby defining a first active region OD1, a second active region OD2 and a channel region CR, in which the channel region CR is located between the first active region OD1 and the second active region OD2. In some embodiments, the patterned isolations 150a, 150b and 150c are formed from field oxide (FOX). A NDDD region 160 is disposed in the first active region OD1. A N+ heavily doped drain region 162 is disposed in the NDDD region 160, in which a drain voltage V_{D1} is applied to the N+ heavily doped drain region 162. A P-body diffused region 170 is disposed in the second active region OD2, in which the NDDD region 160 and the P-body diffused region 170 are spaced at a first predetermined distance R₁ for exposing the semiconductor substrate 100. A neighboring pair of a N+ heavily doped source region 172 and a P+ heavily doped source region 174 is disposed in the P-body diffused region 170, in which a voltage V_{SB1} (voltage source-to-body) is applied to the neighboring pair of the N+ heavily doped source region 172 and the P+ heavily doped source region 174. A first gate structure 180 is disposed above the channel region CR and a second gate structure 190 is disposed above the second active region OD2, in which the second gate structure 190 and the first gate structure 180 are spaced at a second predetermined distance R₂. In some embodiments, the second predetermined distance R₂ is in a range substantially from 0.1 μm to 10 μm. In alternative embodiments, a length of the first gate structure 180 is in a range substantially from 1 nm to 1000 nm

According to some embodiments, an input voltage V_{I1} is always applied to the first gate structure 180, but a gate voltage V_{G1} is applied to the second gate structure 190 for conducting the defined channel region CR when required. Optionally, the input voltage V_{I1} is applied by a drain electrode or an independent electrode. In detailed, the LDNMOS device 10 may be used as a switch. For example, the second gate structure 190 has an extending portion 192 extending from an interface toward the first gate structure 180 and disposed on the channel region CR, in which the interface is located between the P-body diffused region 170 and the channel region CR. When the input voltage V_{I1} is always ON and the gate voltage V_{G1} is OFF, the channel region CR is not conducted because the channel region CR below the extending portion 192 is not conducted. However, the channel region CR below the first gate structure 180 is always conducted. Therefore, Rₒₙ of the LDNMOS device is decreased.

In some embodiments, a ratio of a length of the extending portion 192 to the first predetermined distance R₁ is in a range substantially from 0.13 to 0.52. In alternatively embodiments, the aforementioned ratio is in a range substantially from 0.35 to 0.52.

In certain embodiments, a gate dielectric layer 195 formed from a dielectric material, such as SiO₂, is disposed between the first gate structure 180 and the channel region CR. Other commonly high-k materials, such as carbon, germanium, silicon-germanium, gallium, arsenic, nitrogen, indium, phosphorus, and/or the like, may also be used to form the gate dielectric layer 195. A thickness of the gate dielectric layer 195 is in a range substantially from 12 nm to 100 nm according to the input voltage V_{I1} to the first gate structure 180. In general, when the input voltage V_{I1} is higher, the thicker gate dielectric layer 195 is required so as to avoid being damage to the LDNMOS device 10 itself. For example, the first gate structure 180 is inputted 40V, and the thickness of the gate dielectric layer 195 is preferred 100 nm; or the first gate structure 180 is inputted 5V, and the thickness of the gate dielectric layer 195 is preferred 12 nm. In some embodiments, the gate dielectric layer 195 is further disposed between the second gate structure 190 and the second active region OD2.

In some embodiments, compared with a conventional LDNMOS device with a non-spilt gate structure, the LDNMOS device 10 of the present disclosure has a lower Rₒₙ. For example, Rₒₙ of the LDNMOS device 10 of the present disclosure is in a range substantially from 502.87 to 541.48 ohm, in which the aforementioned extending portion 192 is 0.8 to 1.2 μm, the length of the first gate structure 180 is 0.5 to 0.9 μm, the first predetermined distance R₁ is 2.3 μm, the second predetermined distance R₂ is 0.6 μm, the gate voltage V_{G1} is 5V to 40V and the aforementioned input voltage V_{I1} is in a range substantially from 5V to 40V. Further, the larger input voltage V_{I1} results in the lower Rₒₙ. On the contrary, Rₒₙ of the conventional LDNMOS device is 573.72 ohm, in which a length of the non-spilt gate structure is 2.3 μm and a gate voltage applied on the non-spilt gate structure is 4V. Therefore, the LDNMOS device 10 of the present disclosure has a reduction percent of Rₒₙ ranging about 6 to 12%.

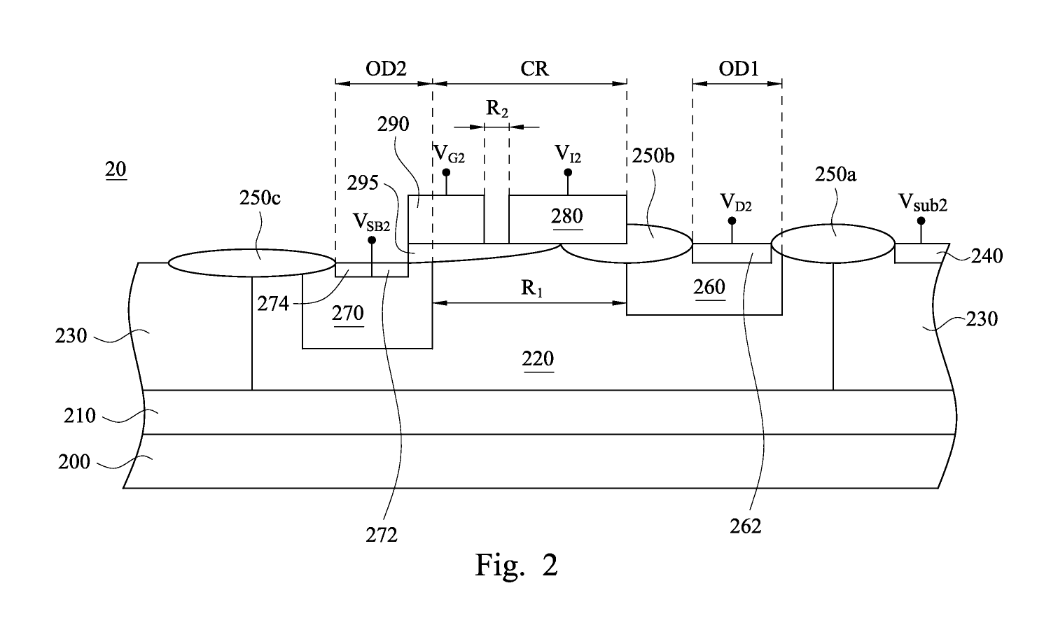

Referring to FIG. 2, FIG. 2 is a schematic diagram showing a LDPMOS device in accordance with another embodiment of the present disclosure. In FIG. 2, a LDPMOS device 20 includes a semiconductor substrate 200 such as a N-type silicon substrate with an epitaxial layer (epi-layer) 210 thereon. The epi-layer 210 includes a high voltage P-well (HVPW) region 220 enclosed by a high voltage N-well (HVNW) region 230. The surface of the high voltage N-well (HVNW) region 230 includes a N+ heavily diffused region 240, in which a substrate voltage V_{sub2} is applied to the N+ heavily diffused region 240.

Patterned isolations 250a, 250b and 250c are disposed on the epi-layer 210, thereby defining a first active region OD1, a second active region OD2 and a channel region CR, in which the channel region CR is located between the first active region OD1 and the second active region OD2. In some embodiments, the patterned isolations 250a, 250b and 250c are formed from field oxide (FOX). A PDDD region 260 is disposed in the first active region OD1. A P+ heavily doped drain region 262 is disposed in the PDDD region 260, in which a drain voltage V_{D2} is applied to the P+ heavily doped drain region 262. A N-body diffused region 270 is disposed in the second active region OD2, in which the PDDD region 260 and the N-body diffused region 270 are spaced at a first predetermined distance R₁ for exposing the semiconductor substrate 200. A neighboring pair of a P+ heavily doped source region 272 and a N+ heavily doped source region 274 is disposed in the N-body diffused region 270, in which a voltage V_{SB2} (voltage source-to-body) is applied to the neighboring pair of the N+ heavily doped source region 272 and the P+ heavily doped source region 274. A first gate structure 280 is disposed above the channel region CR and a second gate structure 290 is disposed above the second active region OD2, in which the second gate structure 290 and the first gate structure 280 are spaced at a second predetermined distance R₂.

Similar to the LDNMOS device 10 of the aforementioned embodiments, an input voltage V₁₂ is always applied the first gate structure 280 for decreasing Rₒₙ of the LDPMOS device 20, and a gate voltage V_{G2} is applied to the second gate structure 290 for conducting the defined channel region CR when required. Therefore, the FOM of the LDNMOS device 10 and the LDPMOS device 20 can be also promoted.

Although the present disclosure has been described above as in detailed description, it is not used to limit the present disclosure. It will be intended to those skilled in the art that various modifications and variations can be made to the structure of the present disclosure without departing from the scope or spirit of the disclosure. Therefore, the scope of the disclosure is to be defined solely by the appended claims.

1. A lateral diffused N-type metal oxide semiconductor (LDNMOS) device, comprising:
a semiconductor substrate;
an epi-layer on the semiconductor substrate;
a patterned isolation layer disposed on the epi-layer, thereby defining a first active region, a second active region and a channel region, wherein the channel region is located between the first active region and the second active region;
a N-type double diffused drain (NDDD) region disposed in the first active region;
a N+ heavily doped drain region disposed in the NDDD region;
a P-body diffused region disposed in the second active region, wherein the NDDD region and the P-body diffused region are spaced at a first predetermined distance to expose the epi-layer;
a neighboring pair of a N+ heavily doped source region and a P+ heavily doped source region disposed in the P-body diffused region; and
a first gate structure disposed above the channel region; and
a second gate structure disposed above the second active region, wherein the second gate structure and the first gate structure are spaced at a second predetermined distance.

2. The device of claim 1, wherein the second gate structure has an extending portion extending from an interface toward the first gate structure and disposed on the channel portion, wherein the interface is located between the P-body diffused region and the channel region.

3. The device of claim 2, wherein a ratio of a length of the extending portion to the first predetermined distance is in a range substantially from 0.13 to 0.52.

4. The device of claim 2, wherein a ratio of a length of the extending portion to the first predetermined distance is in a range substantially from 0.35 to 0.52.

5. The device of claim 1, wherein the second predetermined distance is in a range substantially from 0.1 μm to 10 μm.

6. The device of claim 1, further comprising a gate dielectric layer disposed between the first gate structure and the channel region.

7. The device of claim 6, wherein a thickness of the gate dielectric layer is in a range substantially from 12 nm to 100 nm.

8. The device of claim 6, wherein the gate dielectric layer is formed from SiO₂.

9. The device of claim 6, wherein the gate dielectric layer is disposed between the second gate structure and the second active region.

10. The device of claim 1, wherein a length of the first gate structure is in a range substantially from 1 nm to 1000 nm.

11. A lateral diffused P-type metal oxide semiconductor (LDPMOS) device, comprising:
a semiconductor substrate;
an epi-layer on the semiconductor substrate;
a patterned isolation layer disposed on the epi-layer, thereby defining a first active region, a second active region and a channel region, wherein the channel region is located between the first active region and the second active region;
a P-type double diffused drain (PDDD) region disposed in the first active region;
a P+ heavily doped drain region disposed in the PDDD region;
a N-body diffused region disposed in the second active region, wherein the PDDD region and the N-body diffused region are spaced at a first predetermined distance to expose the epi-layer;
a neighboring pair of a P+ heavily doped source region and a N+ heavily doped source region disposed in the N-body diffused region; and
a first gate structure disposed above the channel region; and
a second gate structure disposed above the second active region, wherein the second gate structure and the first gate structure are spaced at a second predetermined distance.

12. The device of claim 11, wherein the second gate structure has an extending portion extending from an interface toward the first gate structure and disposed on the channel portion, wherein the interface is located between the P-body diffused region and the channel region.

13. The device of claim 12, wherein a ratio of a length of the extending portion to the first predetermined distance is in a range substantially from 0.13 to 0.52.

14. The device of claim 12, wherein a ratio of a length of the extending portion to the first predetermined distance is in a range substantially from 0.35 to 0.52.

15. The device of claim 11, wherein the second predetermined distance is in a range substantially from 0.1 μm to 10 μm.

16. The device of claim 11, further comprising a gate dielectric layer disposed between the first gate structure and the channel region.

17. The device of claim 16, wherein a thickness of the gate dielectric layer is in a range substantially from 12 nm to 100 nm.

18. The device of claim 16, wherein the gate dielectric layer is formed from SiO₂.

19. The device of claim 16, wherein the gate dielectric layer is disposed between the second gate structure and the second active region.

20. The device of claim 11, wherein a length of the first gate structure is in a range substantially from 1 nm to 1000 nm.
